(19) United States
(12) Patent Application Publication
(10) Pub. No.: US 2019/0260398 A1
(43) Pub. Date: Aug. 22, 2019

(54) DESIGN OF PUNCTURING PATTERN FOR POLAR CODES

(71) Applicant: NEC Corporation, Minato-ku, Tokyo (JP)

(72) Inventors: Prakash CHAKI, Tokyo (JP); Norifumi KAMIYA, Tokyo (JP)

(73) Assignee: NEC Corporation, Minato-ku, Tokyo (JP)

(21) Appl. No.: 16/342,584

(22) PCT Filed: Oct. 21, 2016
(86) PCT No.: PCT/JP2016/004661

§ 371 Date: Apr. 17, 2019

(51) Int. Cl. H03M 13/00; H03M 13/13

(52) U.S. Cl. CPC H03M 13/6368; H03M 13/616; H03M 13/13; H03M 13/618

(57) ABSTRACT

A communication device includes: an encoder that encodes an input vector to output a codeword of Polar Code; a memory configured to store a frozen set of positions of frozen bits and a puncturing set of positions of punctured bits; and at least one processor configured to execute a set of instructions to: a) set the frozen set such that a punctured bit has a constant value; b) select the position of a punctured bit such that a minimum number of indices get frozen; c) freeze an index that has a highest decoding error probability among a plurality of indices selected according to the step b); d) repeat the steps b) and c) a predetermined number of times to obtain an array of indices; and e) perform a bit-reversal permutation of the array obtained in the step d) to generate the positions of the punctured bits in the puncturing set.

### TECHNICAL FIELD

The present invention relates to a communication apparatus using Polar Codes, and particularly to puncturing techniques for Polar Codes.

### BACKGROUND ART

Polar Codes are the first family of capacity-achieving codes in Binary-Input Discrete Memoryless Symmetric (BI-DMS) class of channels. As introduced in NPL 1, The key principle of Polar Codes is based on a linear transform called Polar Transform which is performed on N copies of a BI-DMS channel that turns these N channel copies to extreme channels, i.e., either completely noiseless bit-channels (capacity=1) or completely noisy bit-channels (capacity=0). For very large N (asymptotically), it can be proved that the fraction of noiseless bit-channels approach the capacity of the underlying BI-DMS channel. Thus, information bits can then be put in the noiseless bit positions and the remaining bit positions can be filled with a known bit pattern (like all-zero pattern) and encoding can be done following that. Since Polar Codes have code lengths which are only the n-th power of two (n=1, 2, . . . ), constructing Polar Codes of different lengths is important for many applications.

A puncturing mechanism is an exemplary technique for constructing Polar Code codewords of variable rate and length. Puncturing is a method that refers to removing some of the bits from the codeword before transmission. Thus by puncturing M bits from a codeword of code length N, a punctured codeword of length N−M can be obtained which is then transmitted to the receiver. The receiver may implement an inverse operation called, de-puncturing by which it may construct a vector of length N and feed to the decoder for decoding.

NPL 2 introduces rate-compatible punctured Polar Codes where M puncturing positions are chosen by the following steps: i) an all-ones vector of length N is constructed and then the first M bits are filled with 0; ii) then, a bit-reversal permutation operation is performed on this vector; and iii) finally, the positions of the zero bits are used for puncturing. After puncturing, the punctured codeword of length N−M is transmitted.

NPL 3 introduces another puncturing method where the puncturing pattern is designed such that the punctured bits turn out to be zero. This is achieved by freezing the bit-channels that affect the punctured positions. Specifically, the indices of the M rightmost columns of the Generator matrix of polar codes are punctured and correspondingly the last M bit-channels are frozen.

### CITATION LIST

### Non Patent Literature

### [NPL 1]

E. Arikan, “Channel polarization: A method for constructing capacity-achieving codes for symmetric binary-input memoryless channels”, IEEE Transactions of Information Theory, vol. 55, pp. 3051-3073, July 2009.

### [NPL 2]

K. Niu, K. Chen and J. R. Lin, “Beyond Turbo Codes: Rate Compatible punctured Polar Codes”, in proceedings of IEEE ICC, Budapest, Hungary June 2013, pp. 3423-3427.

### [NPL 3]

R. Wang and R. Liu, “A Novel Puncturing Scheme for Polar Codes”, IEEE Communication Letters, VOL. 18, NO. 12, December 2014.

### SUMMARY

According to the punctured Polar Codes as disclosed in the NPL2, the decoder at the receiver does not know the value of the punctured bits. Accordingly, the initial log-likelihood ratio (LLR) values are set to zero at the punctured bits and then the LLR vector is provided as input to the Successive Cancellation (SC) or Successive Cancellation List (SCL) decoder. This may increase the decoding error probability at the punctured positions.

According to the puncturing scheme disclosed in the NPL3, selection of frozen set to have constant punctured bits is done only by selecting any one of all the available weight−1 columns from the generator matrix or by selecting the rightmost column of the generator matrix. In other words, the puncturing scheme of NPL3 does not assure that the selected one of the available weight−1 columns has a higher value of decoding error probability, compared with others of all the available weight−1 columns. Accordingly, the puncturing scheme of NPL3 develops such a problem that the M best channel indices (i.e., the M bit-channels with least value of decoding error probability) may be frozen. This is a serious technical problem because information bit may be transmitted on the bad bit-channels.

An objective of the present invention is to provide a puncturing technique for Polar Codes which can achieve design of length-compatible or rate-compatible Polar Codes with reducing decoding error probability.

According to the present invention, a communication device comprising: an encoder that encodes an input vector to output a codeword of Polar Code; a memory that is configured to store a frozen set of positions of frozen bits and a puncturing set of positions of punctured bits; and at least one processor that is configured to execute a set of instructions to: a) set the frozen set such that a punctured bit has a constant value; b) select the position of a punctured bit such that a minimum number of indices get frozen; c) freeze an index that has a highest decoding error probability among a plurality of indices selected according to the step b); d) repeat the steps b) and c) a predetermined number of times to obtain an array of indices; and e) perform a bit-reversal permutation of the array obtained in the step d) to generate the positions of the punctured bits in the puncturing set.

According to the present invention, a communication system comprising: a sender apparatus comprising the communication device as mentioned above; and a receiver apparatus comprising a decoder that decodes encoded codeword received from the sender apparatus, wherein a constant value of punctured bits is known to the decoder.

According to the present invention, a puncturing method for Polar Codes, comprising: a) setting the frozen set such that a punctured bit has a constant value; b) selecting the position of a punctured bit such that a minimum number of indices get frozen according to the step a); c) freezing an index that has a highest decoding error probability among a plurality of indices according to the steps a) and b); d) repeating the steps a) to c) a predetermined number of times to obtain an array of indices; and e) performing a bit-reversal permutation of the array obtained in the step d) to generate the positions of the punctured bits in the puncturing set.

According to the present invention, a program to function a computer as a sender device including an encoder for Polar Codes, the program comprising a set of instructions to: a) set the frozen set such that a punctured bit has a constant value; b) select the position of a punctured bit such that a minimum number of indices get frozen according to the step a); c) freeze an index that has a highest decoding error probability among a plurality of indices according to the steps a) and b); d) repeat the steps a) to c) a predetermined number of times to obtain an array of indices; and e) perform a bit-reversal permutation of the array obtained in the step d) to generate the positions of the punctured bits in the puncturing set.

As described above, the puncturing technique for Polar Codes according to the present invention can achieve design of length-compatible or rate-compatible Polar Codes with reducing decoding error probability.

The invention accordingly comprises the several steps and the relation of one or more of such steps with respect to each of the others, and the apparatus embodying features of construction, combinations of elements and arrangement of parts that are adapted to affect such steps, all is exemplified in the following detailed disclosure, and the scope of the invention will be indicated in the claims. In addition to the objects mentioned, other obvious and apparent advantages of the invention will be reflected from the detailed specification and drawings.

### BRIEF DESCRIPTION OF DRAWINGS

FIG. 1 is a schematic diagram illustrating a functional configuration of a sender device according to an exemplary embodiment of the present invention.

FIG. 2 is a schematic diagram illustrating a functional configuration of a receiver device according to the exemplary embodiment.

FIG. 3 is a flowchart illustrating an operation of determining the puncturing set according to the exemplary embodiment.

FIG. 4 is a flowchart showing an operation of determining the frozen set according to the exemplary embodiment.

FIG. 5 is a flowchart showing an encoding operation in the sender device according to the exemplary embodiment.

FIG. 6 is a schematic diagram showing a decoding operation in the receiver device according to the exemplary embodiment.

FIG. 7 is a schematic diagram illustrating a determinant using an example of the generator matrix of Polar codes for explaining a first example of the exemplary embodiment.

FIG. 8 is a diagram illustrating a matrix to explain a first step of determining the puncturing set and frozen set according to the exemplary embodiment of the present invention.

FIG. 9 is a diagram illustrating the matrix to explain a second step A of determining the puncturing set following the first step shown in FIG. 8.

FIG. 10 is a diagram illustrating the matrix to explain a second step B of determining the frozen set following the second step A shown in FIG. 9.

FIG. 11 is a diagram illustrating the matrix to explain a third step A of determining the puncturing set following the second step B shown in FIG. 10.

FIG. 12 is a diagram illustrating the matrix to explain a third step B of determining the frozen set following the third step A shown in FIG. 11.

FIG. 13 is a diagram illustrating the matrix to explain a fourth step A of determining the puncturing set following the third step B shown in FIG. 12.

FIG. 14 is a diagram illustrating the matrix to explain a fourth step B of determining the frozen set following the fourth step A shown in FIG. 13.

FIG. 15 is a diagram illustrating the matrix to explain a fifth step A of determining the puncturing set following the fourth step B shown in FIG. 14.

FIG. 16 is a diagram illustrating the matrix to explain a fifth step B of determining the frozen set following the fifth step A shown in FIG. 15.

FIG. 17 is a diagram illustrating the matrix to explain a sixth step A of determining the puncturing set following the fifth step B shown in FIG. 16.

FIG. 18 is a diagram illustrating the matrix to explain a sixth step B of determining the frozen set following the sixth step B shown in FIG. 17.

FIG. 19 is a diagram illustrating an example of data stored in the puncturing set memory and the frozen set memory according to the exemplary embodiment.

FIG. 20 is a diagram illustrating an alternative algorithm for determining the puncturing set and frozen set according to another example of the exemplary embodiment of the present invention.

FIG. 21 is a schematic diagram showing the steps of systematic encoding according to the exemplary embodiment of the present invention.

FIG. 22 is a schematic diagram showing the steps of systematic decoding according to the exemplary embodiment of the present invention.

FIG. 23 is a schematic diagram showing the steps of generating a puncturing pattern according to a second example of the exemplary embodiment of the present invention.

FIG. 24 is a diagram illustrating a matrix to explain a method of generating a puncturing array according to the second example of the exemplary embodiment of the present invention.

### DETAILED DESCRIPTION

Hereinafter, the word “exemplary” is used herein to mean “serving as an example, instance, or illustration”. Any embodiment described herein as “exemplary” is not necessarily to be construed as preferred or advantageous over other embodiments.

### 1. OUTLINE OF EXEMPLARY EMBODIMENTS

The conventional technical problems as discussed above can be solved by one or more variants of the exemplary embodiments of the present invention. More specifically, puncturing positions are chosen in a way that they eventually become constant-valued. This is achieved by using the property of Polar Codes such that N−K bit-channels are set frozen with a constant value which are previously known to the decoder. A set of puncturing positions is first chosen and then the bit-channels that affect those puncturing positions are set to be frozen.

Usually, choosing a puncturing position has no relation with frozen set. According to an exemplary embodiment of the present invention, a relation between frozen set and puncturing set is defined. More specifically, the frozen set is chosen such that the punctured bits have constant value. Since the punctured bits have constant value, the decoder in the receiver may be informed of this constant value in advance, thus not requiring any decoding for the punctured bits. The punctured bits are chosen such that a minimum number of indices get frozen and indices with relatively higher decoding error probability get frozen. More detailed method will be described in the paragraphs that follow.

### 1.1) Two-Stage Selection of Puncturing Set

In the method of selecting the puncturing positions, two-stage selection is done to select the optimal bit-channels based on a generator matrix for Polar Codes. In the first stage, the columns in the generator matrix with weight one (1) are listed up. This operation ensures that only one bit-channel gets frozen in the attempt to make the punctured bit to be constant-valued. In the second stage, among all the column indices of weight 1, the index that has the highest value of decoding error probability is selected for puncturing. Then the column and the row with that selected index number are deleted or replaced with an all-zero column and row respectively. At the end of each step of the two-stage selection process, one puncturing position is obtained which is constant-valued.

By repeating the above-described two-stage selection process M times, it is possible to obtain an array of M constant-valued puncturing positions, which is hereafter referred to as a puncturing array. The final puncturing set containing the indices that has to be punctured in the output codeword may be obtained by performing a bit-reversal permutation operation on the puncturing array. The reason why the M puncturing positions become constant-valued is that the row indices (i.e., bit-channels) corresponding to the puncturing positions are set to be frozen. In Polar Codes, frozen set indices contain a fixed value (for e.g., 0 bit) which is known to the decoder in advance. Thus it is possible to make the puncturing positions contain a fixed value. As mentioned before, this is done by including the bit-channels (i.e., row indices of the generator matrix) that affect the punctured bits into the frozen set. In the present exemplary embodiment, the frozen set gets modified. The details will be described hereafter.

### 1.2) Frozen Set

In the original Polar Codes, the frozen set is chosen based on the decoding error probabilities of the polarized bit-channels. This can be captured by a metric called, Bhattacharyya parameter which may be considered to be an upper-bound on the decoding error probability. One way of finding the Bhattacharyya parameters (also referred to as Z parameter) of the polarized bit-channels can be Density Evolution or its Gaussian Approximation. In order to determine the frozen set in original Polar Codes, all the N bit-channels may be sorted according to their post-polarization Z parameter values. Then the N−K bit-channels with the highest value of Z parameter may be selected to be the frozen set. No information may be put in these N−K positions because they are considered to have very high decoding error probability. Instead of information, they may be filled with a constant value that may be known to the decoder in advance. Information bits may be filled in the K remaining positions that have relatively lower values of Z parameter.

In the present exemplary embodiment, the frozen set is modified from the above-mentioned original frozen set. More specifically, the frozen set is constructed in two parts, using two different methods. The first part of the frozen set is constructed based on the puncturing method. In order to make the punctured bits to be constant-valued, the bit-indices affecting the punctured bits are included in the frozen set. Thus, out of all the N−K indices supposed to be contained in the frozen set, M indices are included with the objective of achieving constant-valued punctured bits. The N−K−M remaining indices in the frozen set are chosen using the original approach of selection based on higher values of Z parameter. Thus the frozen set, and correspondingly the non-frozen set, in the present exemplary embodiment may become different from that in the original Polar Codes.

As described above, the two-stage selection method is employed for determining the puncturing pattern. Details on how the two-stage selection works as the optimal will be described hereafter.

The first stage ensures that the minimum number of bit-channels get frozen to achieve the objective of constant-valued punctured bits. It is important to ensure that the puncturing method does not cause freezing of too many bit-channels. The reason is that the frozen set should ideally contain only the bit-channels with very high Z parameter. If some other bit-channel is included in the frozen set based on some parameter (here, to achieve constant punctured bit) other than the high Z parameter condition, then there is a possibility that some bit-channels with low values of Z-parameter may get included in the frozen set. So it is aimed that the least number of bit-channels gets frozen due to the puncturing method. It is possible to ensure that exactly M bit-channels get frozen to achieve the objective of generating M punctured bits with constant values. The remaining N−K−M elements of the frozen set can be chosen to be the N−K−M bit-channels with highest Z parameter. Thus the first goal of restricting the bit-channels frozen due to puncturing to a minimum is ensured by the first stage of selection.

The second stage of selection in the puncturing method ensures that the bit-channels that get included in frozen set owing to puncturing scheme have as high Z value as possible. Thus, the second stage is responsible for selecting the bit-channels that would ensure constant-valued punctured bits, but at the same time, these selected bit-channels would have as high value of Z parameter as possible. Thus, the combination of first-stage and second-stage of selection ensures that the optimal bit-channels get frozen to achieve the objective of constant-valued punctured bits. Here, ‘optimality’ refers to the idea that the bit-channels that get frozen as a result of first and second stages have the highest possible value of sum of Z parameters that meet the objective of constant-valued punctured bits satisfying the constraint that the least number of bit-channels get frozen to meet the objective.

### 1.3) Advantages

As described above, the punctured bits become constant-valued in the present exemplary embodiment. Thus the value of the punctured bits is known to the decoder in advance. If punctured bits are not known to the decoder, then the decoder may set the initial LLR values at the punctured positions to 0. This may increase the decoding error probability at the punctured positions. In the present exemplary embodiment, the decoder may set the initial LLR values of the punctured bits to positive or negative infinity and then proceed with the SC or SCL decoding. This may reduce the Bit Error Rate (BER).

Further, it will be possible to design Polar Codes of various lengths (not necessarily only power of 2) with improved BER performance. In addition, the punctured bits are chosen in a way such that their values are known to the decoder as a prior information, which enables the decoder to decode the bits at the punctured positions without any decoding error.

Furthermore, the frozen set is chosen in such a way that the punctured bits become constant-valued, and at the same time considering that the frozen set consists of indices with as high value of decoding error probability as possible, which may result in reducing the bit error rate of the codeword.

### 2. EXEMPLARY EMBODIMENT

Hereinafter, an exemplary embodiment of the present invention will be discussed in its complete details with accompanying figures and finally explained with an exemplary scenario. The embodiment described herein is only illustrative of some specific representations of the invention acknowledging the fact that the inventive concepts can be embodied in a wide variety of contexts. Thus the exemplary embodiment does not limit the scope of the present invention.

### 2.1) System Configuration

A communication device according to the exemplary embodiment of the present invention will be described as a sender device or a receiver device. The sender device and the receiver device may be integrated into a single communication device.

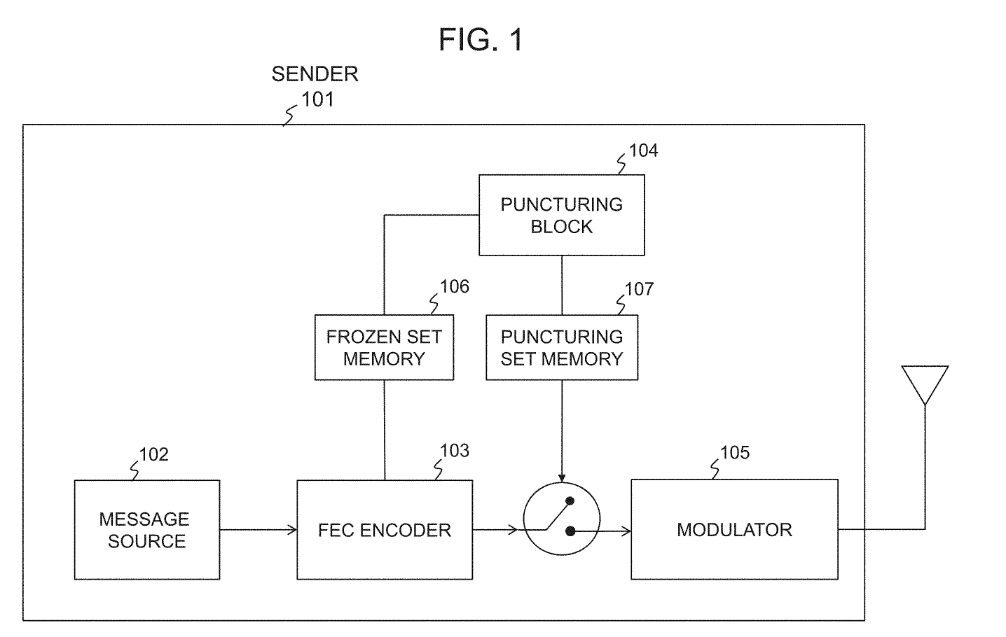

As illustrated in FIG. 1, a sender device 101 is provided with data sending functions including a message source 102, a Forward Error Correction (FEC) encoder 103 of encoding scheme for Polar Codes, a puncturing block 104, and a modulator 105, which may be implemented on a processor running respective programs stored in a memory device (not shown). In the present embodiment, the puncturing block 104 uses a frozen set memory 106 and a puncturing set memory 107 to perform operations of frozen set and puncturing set determination.

The message source 102 generates some information that needs to be encoded and then transmitted. The FEC encoder 103 encodes the information generated by the message source 102 to form a codeword of length N. The puncturing block 104 punctures the codeword generated by the FEC encoder 103 at M positions as specified in the puncturing pattern to obtain a short length punctured codeword of length N−M. The modulator 105 modulates the punctured codeword and then sends it to a radio-frequency (RF) unit for transmission (not shown).

The puncturing block 104 determines and stores part of the frozen set in the frozen set memory 106. For example, the puncturing block 104 determines M elements of the frozen set where M is the number of bits needed to be punctured and then determines the remaining part of the frozen set, i.e., the remaining N−K−M elements of the frozen set based on Z parameter value or equivalently decoding error probability. The frozen set is used in the FEC encoder 103 and the puncturing set is used for codeword puncturing. The details will be described later.

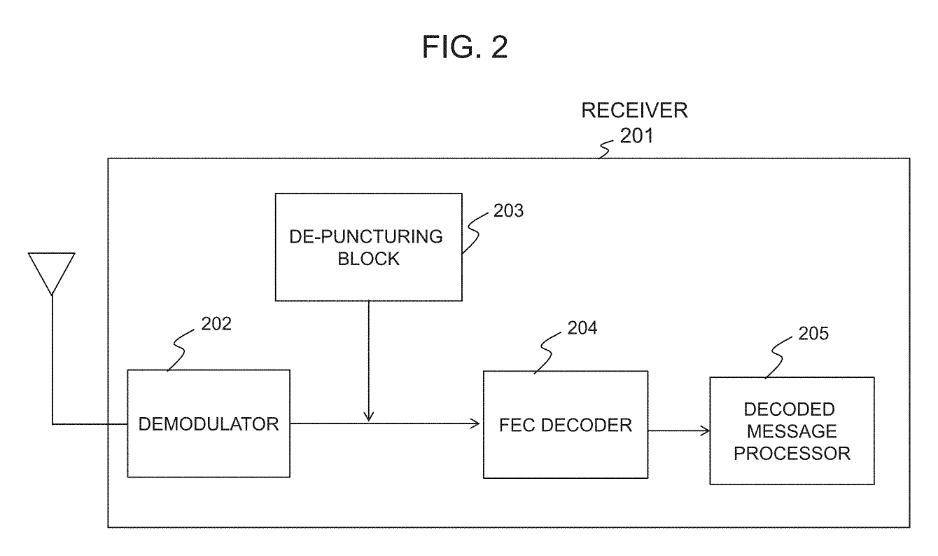

As illustrated in FIG. 2, a receiver device 201 is provided with data receiving functions including a demodulator 202, a de-puncturing block 203, a FEC decoder 204 and a decoded message processor 205, which may be implemented on a processor running respective programs stored in a memory device (not shown). The de-puncturing block 203 creates a N size vector of LLRs. The LLR of the punctured bits may be set to positive or negative infinity and then it is fed as input to the FEC decoder 204. The FEC decoder 204 runs a decoding algorithm on the LLR vector to produce a decoded message, which is output to the decoded message processor 205.

### 2.2) Puncturing Set Determination

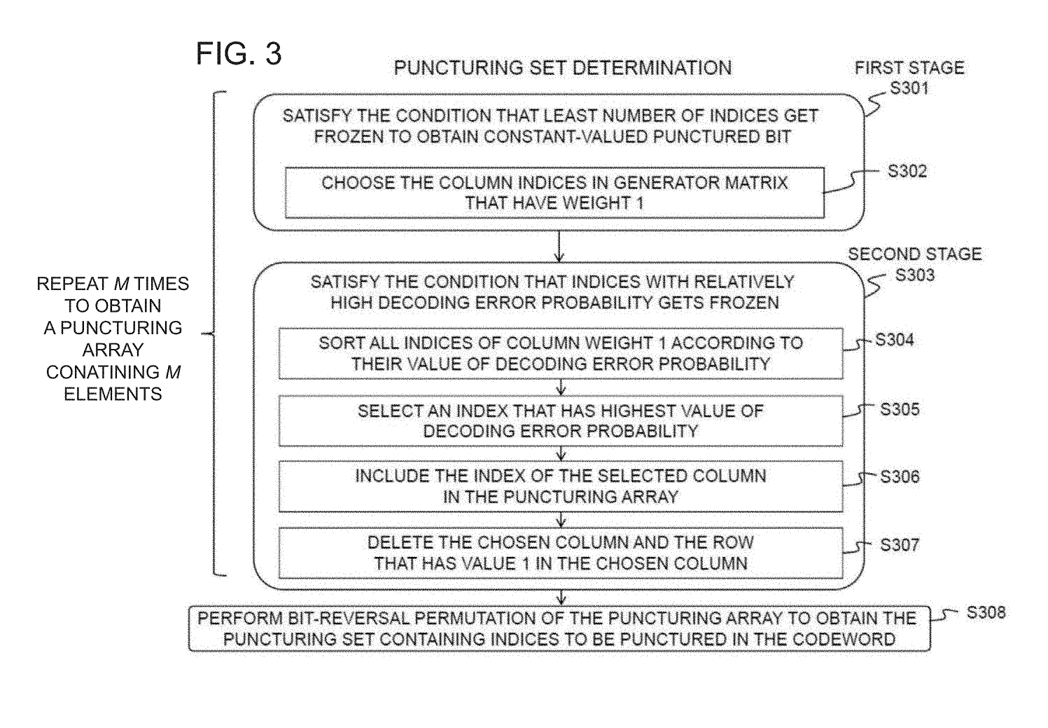

FIG. 3 shows a schematic flowchart explaining the method to determine the puncturing set according to the exemplary embodiment of the present invention. As explained above, a puncturing position can be determined by the two-stage selection method. In the first stage of selection (Operation S301), the condition to be checked is that a chosen puncturing position should freeze a minimum number of bit-channels to become constant-valued. This may be done by choosing the column indices of the generator matrix that have weight 1 (Operation S302).

After the first stage of selection, the second stage of selection (Operation S303) may begin. The condition to be checked here is that among all the indices obtained by the first stage of selection, the index that has the highest value of decoding error probability is selected (Operations S304 and S305). Here, Bhattacharyya parameter (or Z parameter) may be considered as a metric for decoding error probability and may be used for comparison among the indices. The selected index is then included in the puncturing array (Operation S306). Then the column of that selected index and the row(s) having a value of 1 in the selected-index column in the generator matrix are deleted (Operation S307). The deletion of the column may be construed as the puncturing operation and the deletion of the row may be construed as the freezing operation.

There can be many variants of implementing Operation S307 and all variants should be construed to be in the scope of the present invention. In an alternative example of implementation, it may be possible to replace the column and row of the selected index by an all-zero column and row respectively, instead of deleting it.

The combination of the first and second stage operations can be repeated M times to obtain a puncturing array containing M indices. Finally, as shown in Operation S308, a puncturing set containing the indices to be punctured in the output codeword may be obtained by a bit-reversal permutation of the puncturing array obtained in S307.

### 2.3) Frozen Set Determination

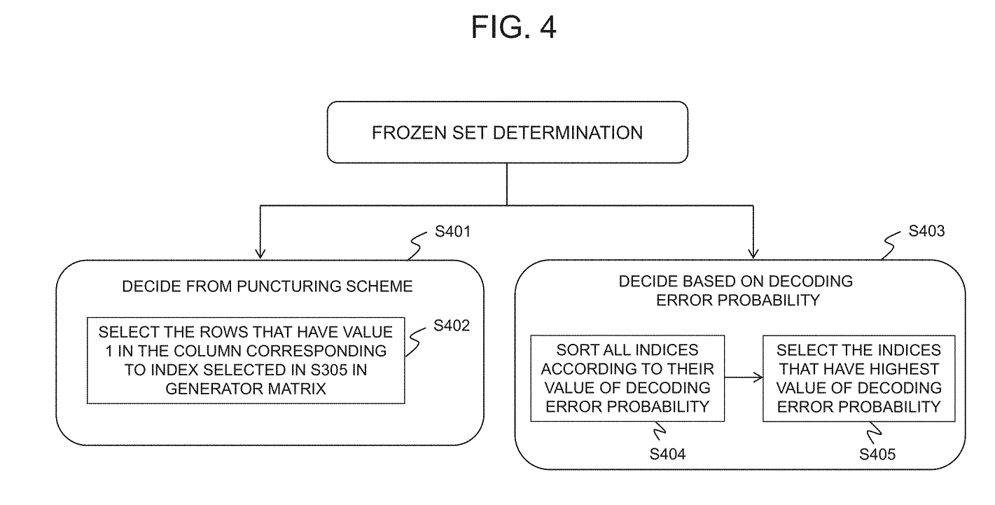

FIG. 4 shows a schematic diagram explaining a method to determine the frozen set according to the exemplary embodiment of the present invention. As explained before, frozen set can be selected in two parts using two different methods. The first part of the frozen set can be selected based on the puncturing scheme (Operation S401). As discussed before in FIG. 3, a column index of the generator matrix can be selected in Operation S305, from which puncturing position can be obtained. Then row(s) having value 1 in the selected-index column (obtained by Operation S305) of the generator matrix is selected and included in the frozen set (Operation S402). In an example, the first part of the frozen set which is determined from the puncturing scheme includes the entire puncturing array which may be obtained by repeating the Operation S301-S307 by M times. Thus, the M indices contained in the puncturing array may constitute M indices of the frozen set.

The remaining N−K−M indices of the frozen set may be determined by a second method (Operation S403). As an example, all the N−M remaining indices which are still unfrozen are sorted according to their decoding error probabilities, or equivalently their Z parameters (Operation 404). Then the N−M−K indices that have the highest value of decoding error probabilities (or equivalently, Z parameters) are selected and included in the frozen set (Operation S405).

### 2.4) Puncturing of Codeword

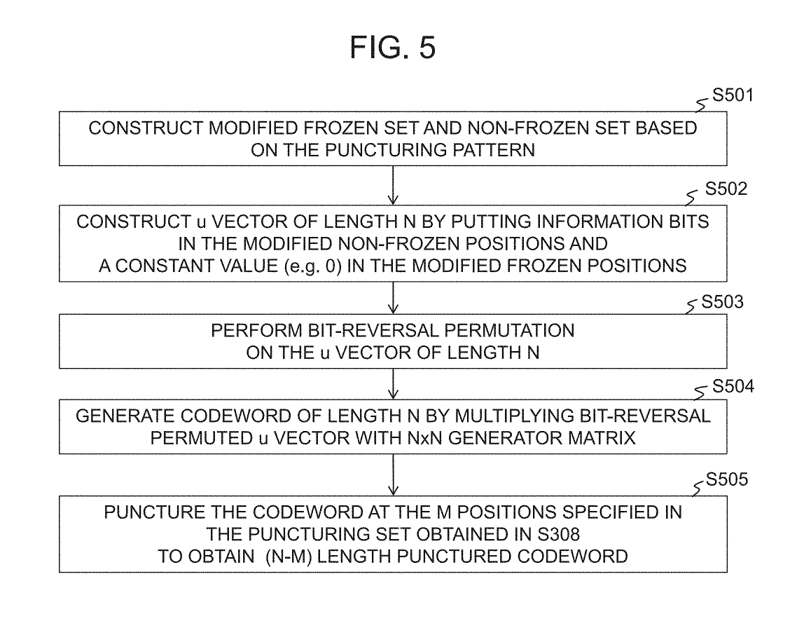

Referring to FIG. 5, the encoding mechanism will be explained according to the exemplary embodiment of the present invention. At first, the modified frozen set is constructed as explained in FIG. 4 and the remaining K indices are included in a non-frozen set (Operation S501). Then a vector of length N called ‘u vector’ is constructed by putting information bits in the K non-frozen positions and a constant value (for e.g., 0 bit) in the frozen index positions (Operation S502). Then a bit-reversal permutation operation is performed on the u vector (Operation S503). The codeword is generated by multiplying the bit-reversal permuted vector with a N×N generator matrix (Operation S504). Finally, the generated codeword is punctured at M positions as specified in the puncturing set obtained in Operation S308 to generate a short length punctured codeword of length N−M (Operation S505).

### 2.5) De-Puncturing

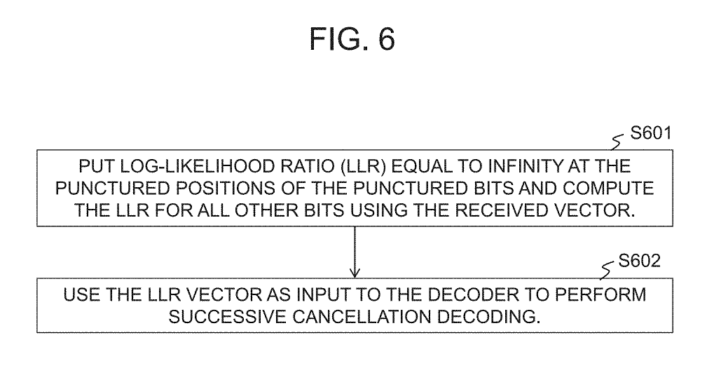

Referring to FIG. 6, the decoding mechanism will be explained according to the exemplary embodiment of the present invention. The de-puncturing block 203 constructs a LLR vector of length N where the LLR value of the punctured bits is set to positive or negative infinity (Operation S601). For example, if the frozen indices are filled with 0 bit before encoding, then the LLR of the punctured bits may be set to positive infinity. The decoder 204 then uses this LLR vector of length N as input and performs decoding (Operation S602). In one exemplary embodiment, the decoder 204 may use one of Successive Cancellation (SC) decoding algorithm, Successive Cancellation List (SCL) decoding algorithm and Cyclic Redundancy Check (CRC)-aided List Decoding Algorithm. The decoder 204 may output a vector of length N which is the decoded message.

### 3. FIRST EXAMPLE

Details of an example of the exemplary embodiment of the present invention will be described in the case of Polar Code.

### 3.1) Outline of Puncturing Method

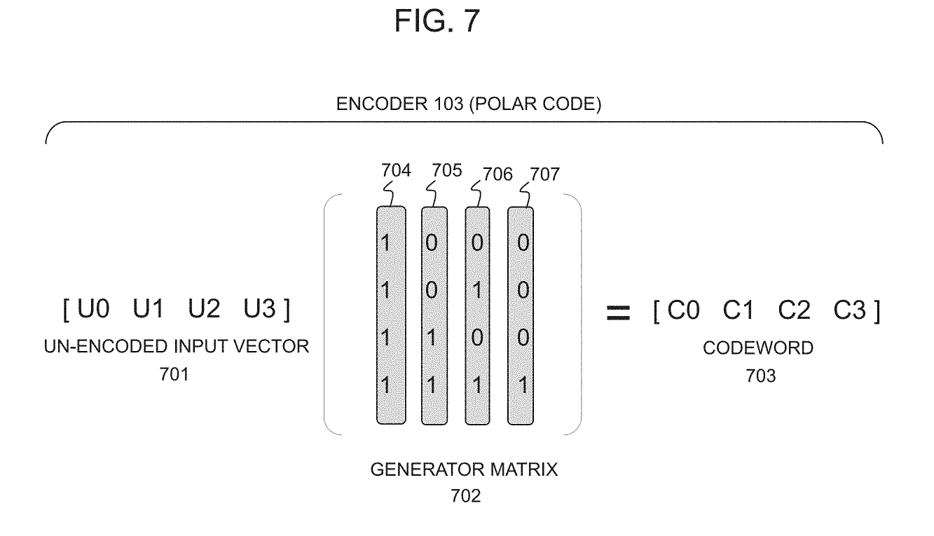

FIG. 7 shows an illustrative equation to further explain the puncturing method according to an exemplary embodiment of the present invention. Assuming a coding mechanism of code length N, an un-encoded input vector 701 where each of the 4 bits are U0, U1, U2 and U3, a 4×4 generator matrix 702 as a base matrix, and an encoded codeword 703 where the code bits are C0, C1, C2 and C3. Each column of the 4×4 generator matrix 702 is shown separately as reference numerals 704, 705, 706 and 707, respectively. As can be seen in this example, the respective code bits C0-C3 of the codeword 703 are represented by
C0=U0+U1+U2+U3,
C1=U2+U3,
C2=U1+U3, and
C3=U3.

Thus, in order to puncture the code bit C0 and make it constant-valued at the same time, all the 4 input bits U0, U1, U2 and U3 have to be frozen. Thus, no information bit can be transmitted. Again, to puncture the code bit C1 and make it constant-valued at the same time, two input bits U2 and U3 have to be frozen. Similarly for the code bit C2, two input bits U1 and U3 have to be frozen. But for the code bit C3, only one input bit U3 has to be frozen. Accordingly, the code bit C3 satisfies the condition that the least number of indices get frozen and therefore is chosen as a puncturing position here. This is the reason why a column of weight 1 is chosen in the first stage of selection of puncturing pattern as shown in FIG. 3. In this case, there is only one column 707 which qualified the first stage of selection. So there is no need to perform the second stage of selection. Then, the column 707 and the last row having the value 1 in the column 707 in the generator matrix 702 are deleted for puncturing and freezing respectively. If one more bit needs to be punctured, then both columns 705 and 706 appear to have weight 1. In that case, the second stage of selection is used to select the one that has a higher value of decoding error probability.

### 3.2) Example of Determination of Puncturing Set and Frozen Set

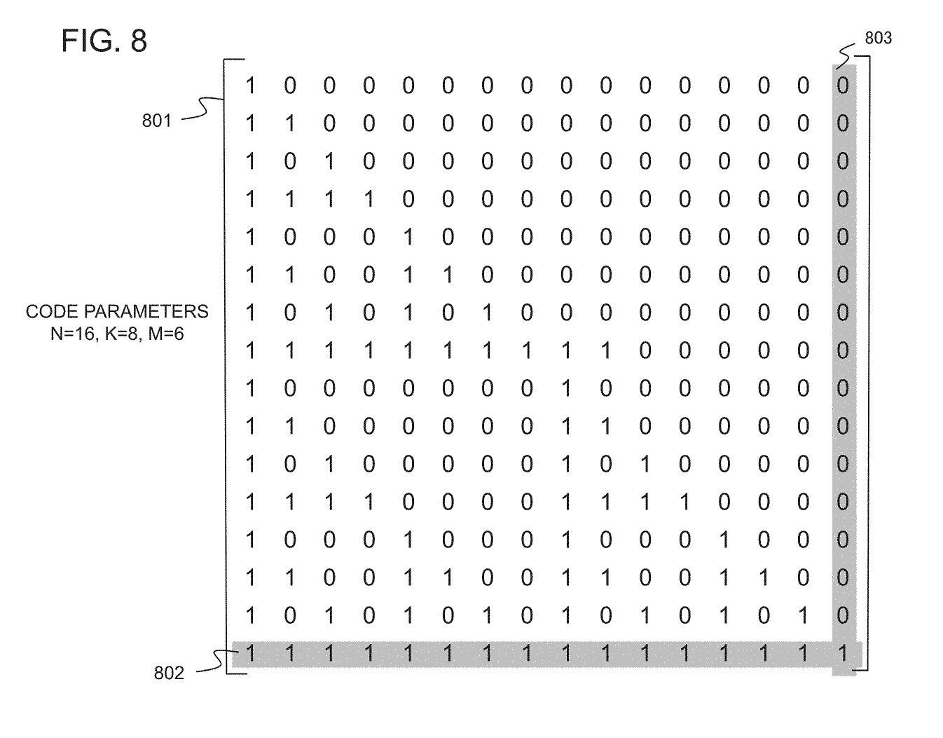

Hereinafter, a generator matrix 801 for a Polar Code of length N=16 is used as a base matrix to further explain an example of the puncturing method by sequentially referring to FIGS. 8-19. The information length K and the number of code bits to be punctured, M, are assumed to be K=8 and M=6, respectively.

As illustrated in FIG. 8, at first, using the first stage of selection, column 803 is selected as it is the only column with weight 1. So the index of the column 803 is included in the puncturing array. The index of the row 802 corresponding to a position of value 1 in the column 803 is included in the frozen set.

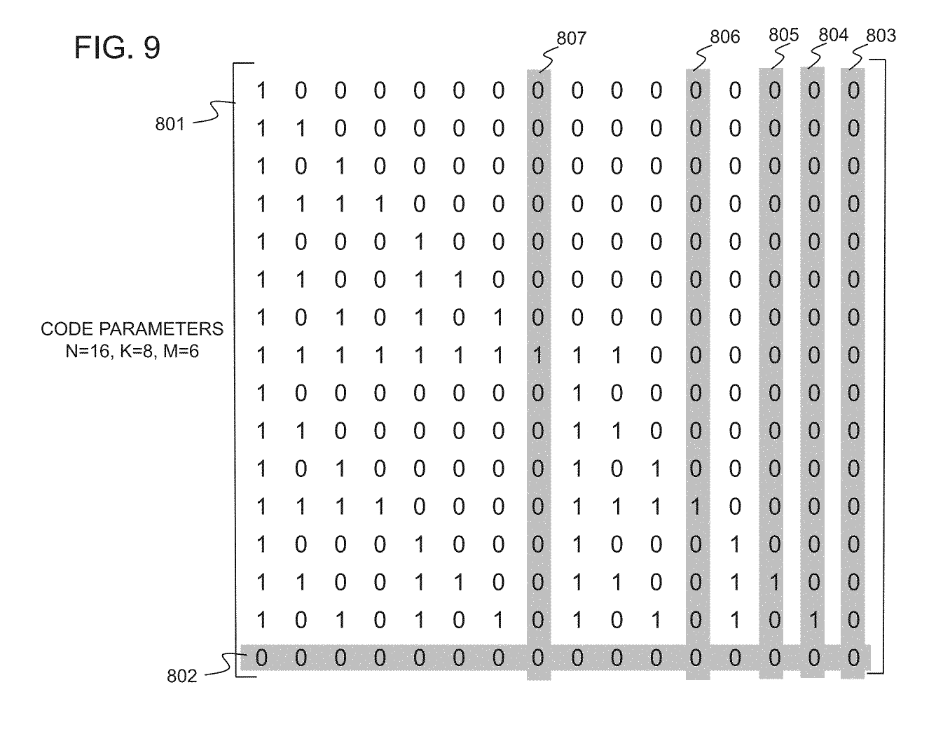

As illustrated in FIG. 9, after selecting the column index of the column 803 in the puncturing array as explained in FIG. 8, the column 803 and the row 802 are deleted or made all zero. Following that, the columns with weight 1 are listed from the remaining columns as the first stage of selection for a second element of the puncturing array. Thus, columns 804, 805, 806 and 807 qualify in the first stage of selection. The indices of the columns 804, 805, 806 and 807 may then be sorted according to decoding error probability (or equivalently, Z parameter) in the second stage of selection of puncturing position. After comparing the decoding error probabilities (or equivalently, Z parameter) of the columns 804, 805, 806 and 807, the index of column 807 is assumed to be selected as it has the maximum Z parameter among them.

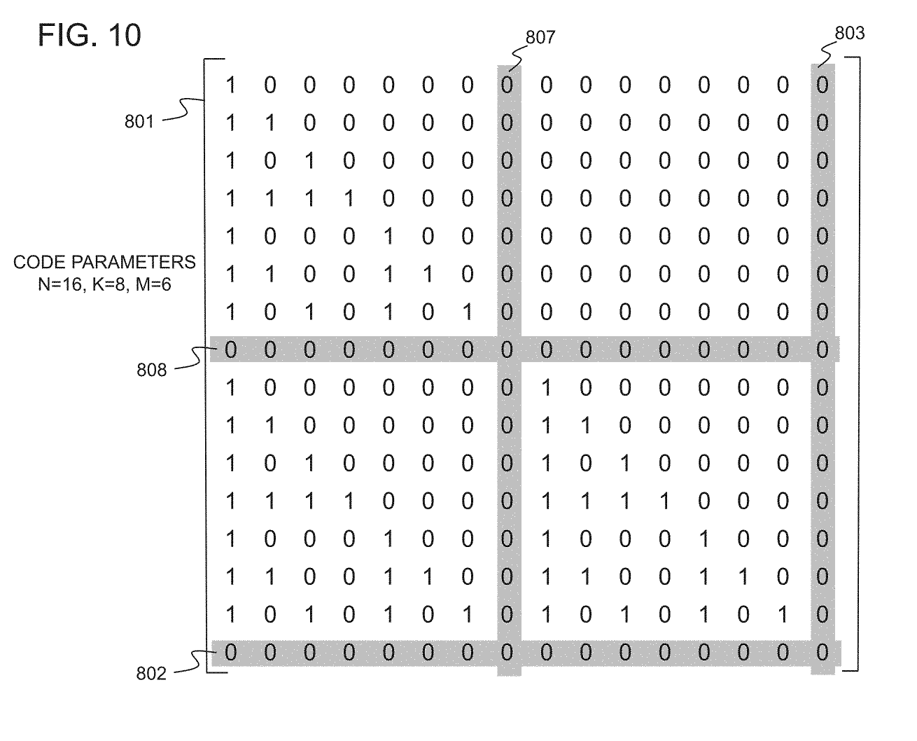

As illustrated in FIG. 10, the column 807 is filled with all zero. Since the row index corresponding to a position of value 1 in the column 807 is the row 808 as shown in FIG. 9, the row 808 is also filled with all zero. The index of the column 807 is included in the puncturing array. The index of the row 808 is included in the frozen set.

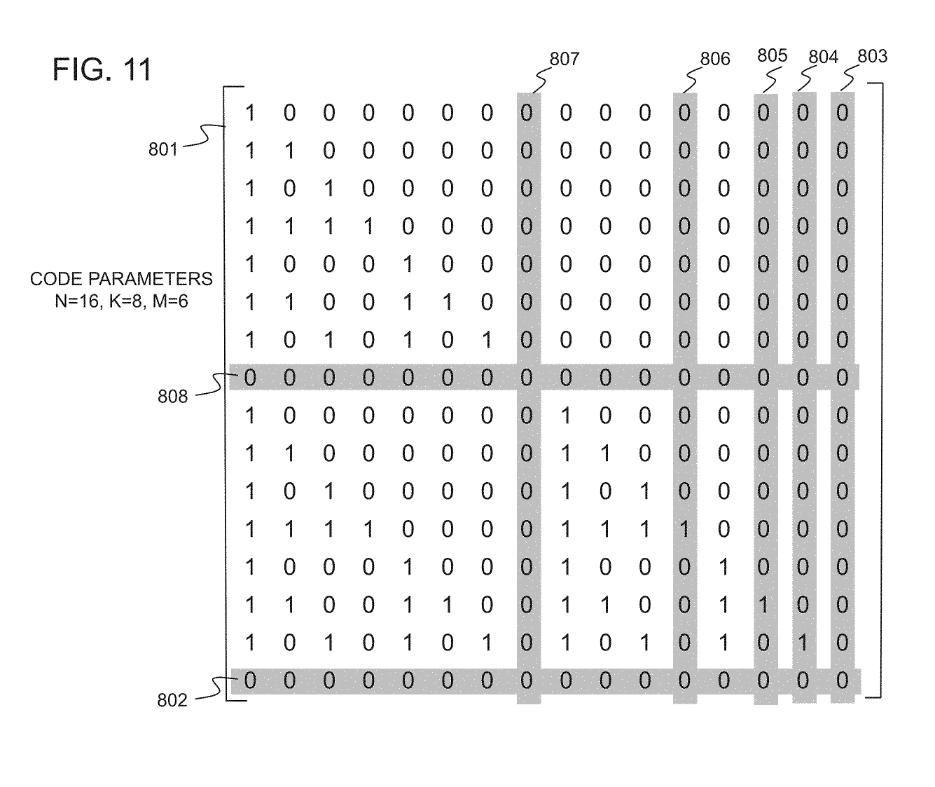

As illustrated in FIG. 11, for selecting a third element in the puncturing array, first stage of selection is again performed to obtain the columns 804, 805 and 806 as columns with column weight 1.

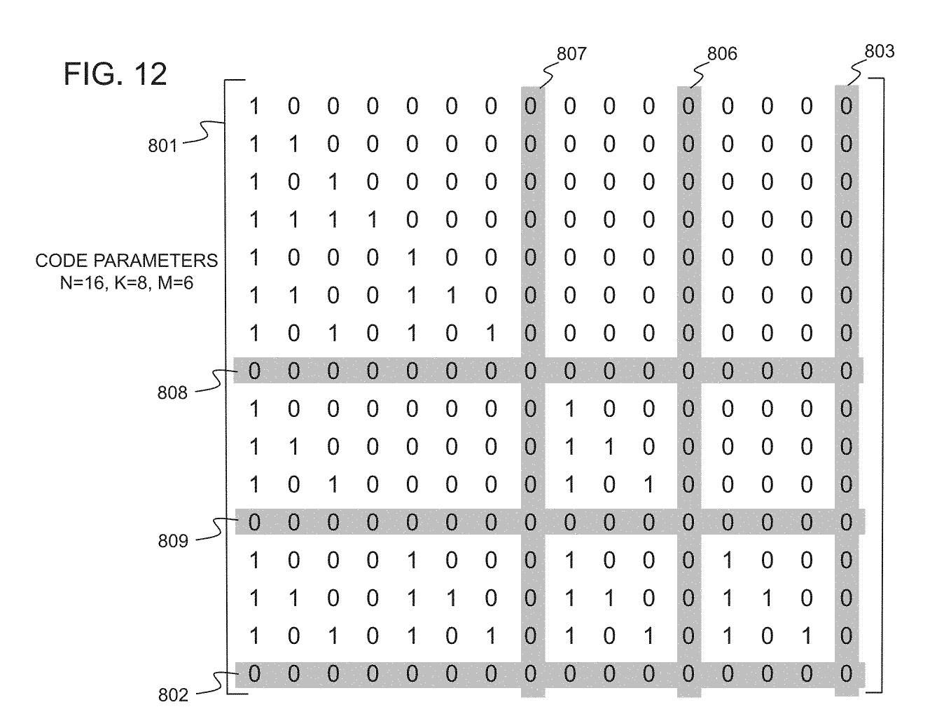

As illustrated in FIG. 12, after comparing the decoding error probabilities (or equivalently, Z parameter) of the indices of the columns 804, 805 and 806, the index of column 806 is assumed to be selected as it has the maximum Z parameter among them. Thus the column 806 is filled with all zero. Since the row index corresponding to a position of value 1 in the column 806 is the row 809, the row 809 is also filled with all zero. The index of the column 806 is included in the puncturing array. The index of the row 809 is included in the frozen set.

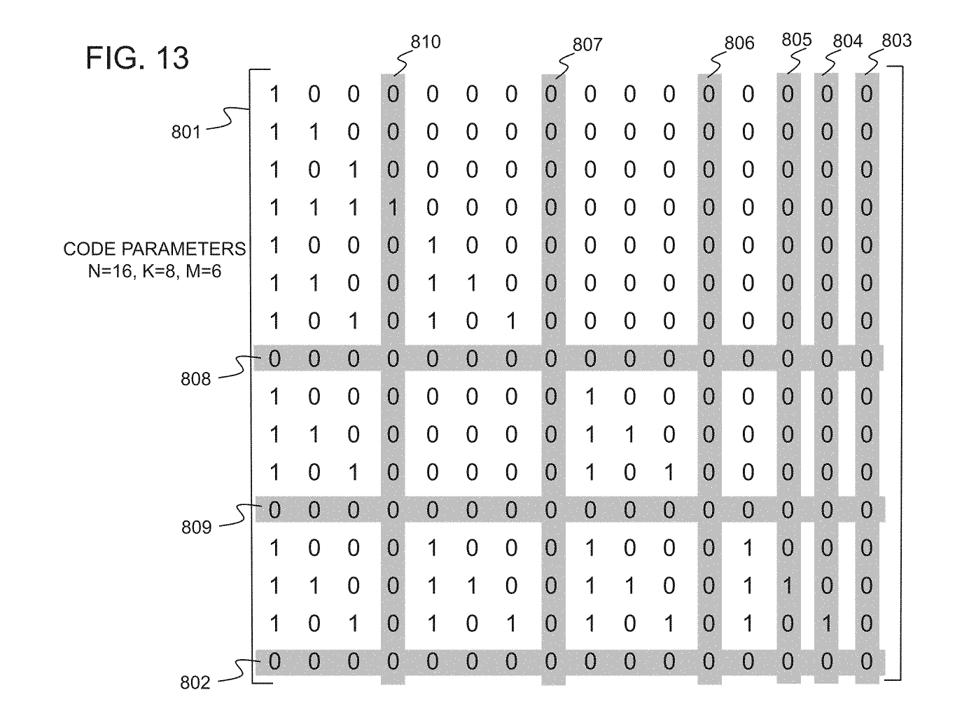

As illustrated in FIG. 13, for selecting the fourth element in the puncturing array, first stage of selection is again performed to obtain the columns 804, 805 and 810 as columns with column weight 1.

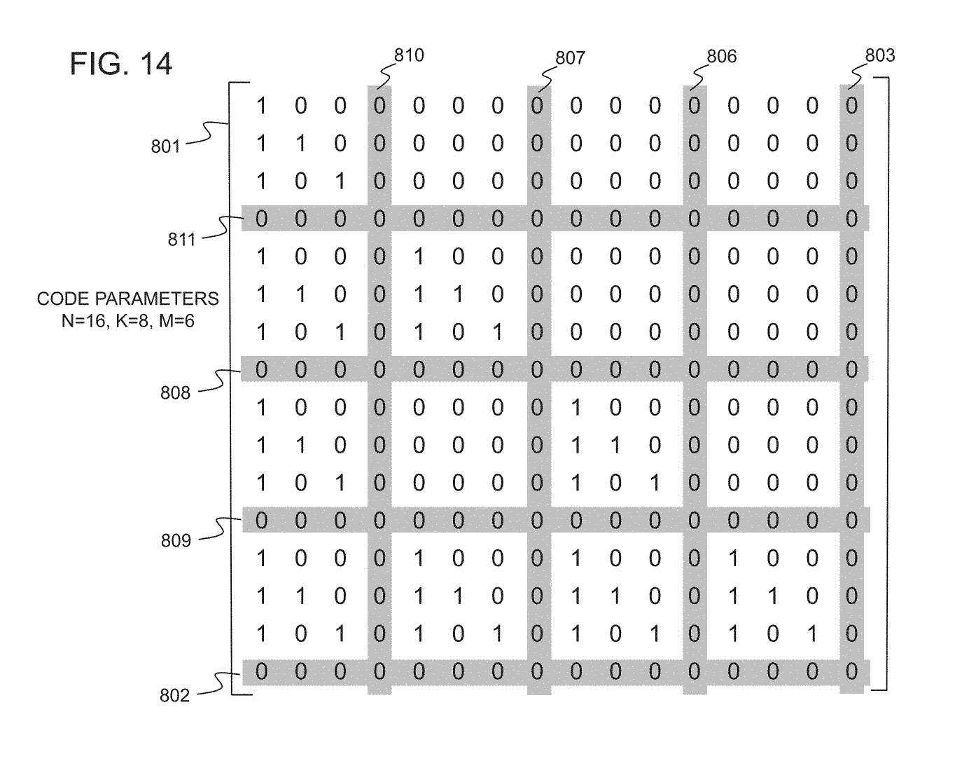

As illustrated in FIG. 14, after comparing the decoding error probabilities (or equivalently, Z parameter) of the indices of the columns 804, 805 and 810, the index of the column 810 is assumed to be selected as it has the maximum Z parameter among them. Thus the column 810 is filled with all zero. Since the row index t corresponding to a position of value 1 in the column 810 is the row 811, the row 811 is also filled with all zero. The index of the column 810 is included in the puncturing array. The index of the row 811 is included in the frozen set.

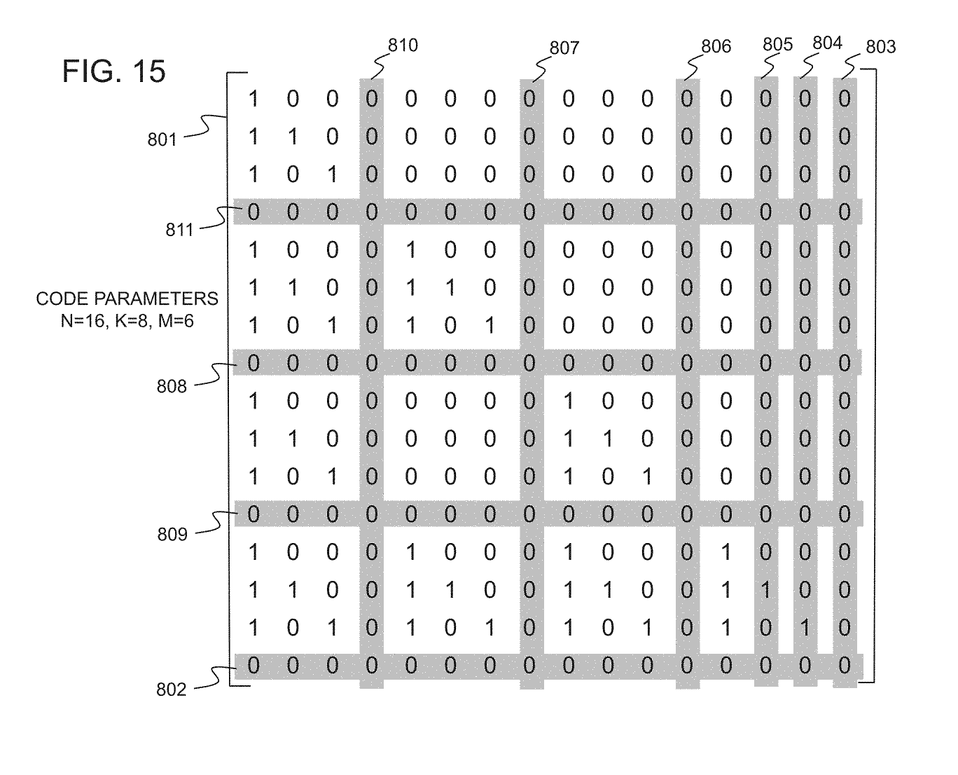

As illustrated in FIG. 15, for selecting the fifth element in the puncturing array, first stage of selection is again performed to obtain the columns 804 and 805 as columns with column weight 1.

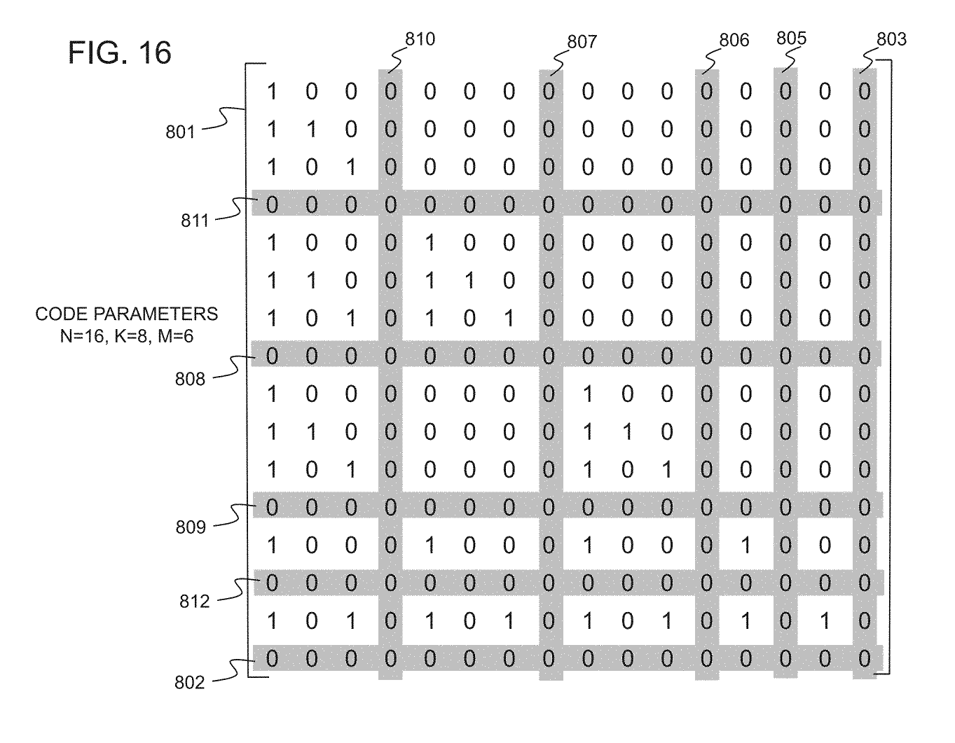

As illustrated in FIG. 16, after comparing the decoding error probabilities (or equivalently, Z parameter) of the indices of the columns 804 and 805, the index of the column S805 is assumed to be selected as it has the maximum Z parameter among them. Thus the column 805 is filled with all zero. Since the row index corresponding to a position of value 1 in the column 805 is the row 812, the row 812 is also filled with all zero. The index of the column 805 is included in the puncturing array. The index of the row 812 is included in the frozen set.

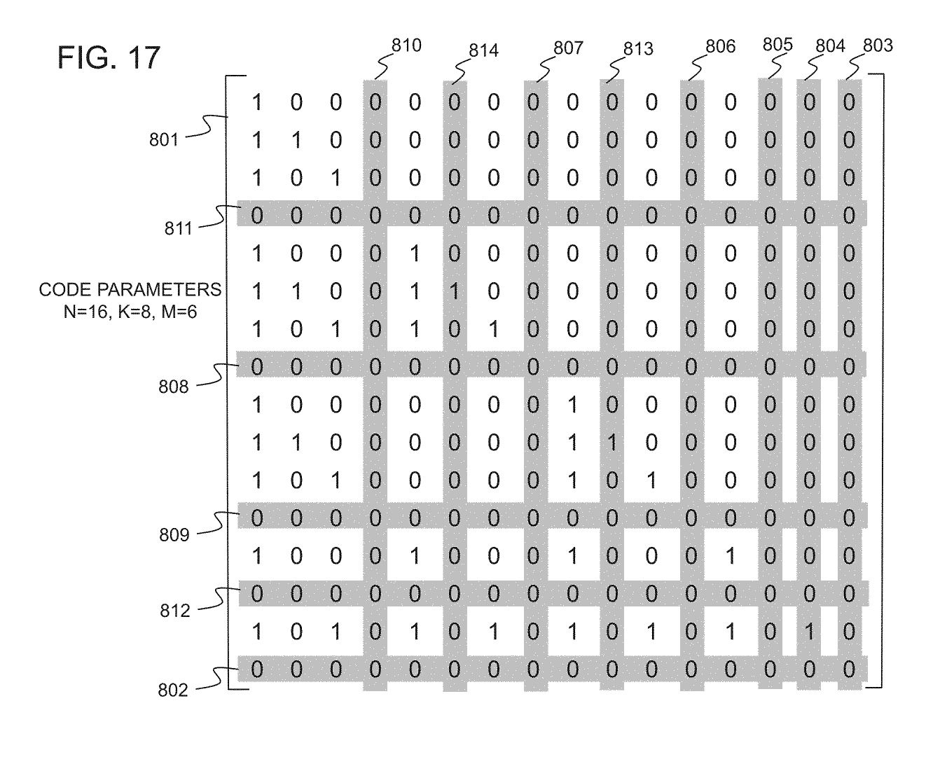

As illustrated in FIG. 17, for selecting the sixth element in the puncturing array, first stage of selection is again performed to obtain the columns 804, 813 and 814 as columns with column weight 1.

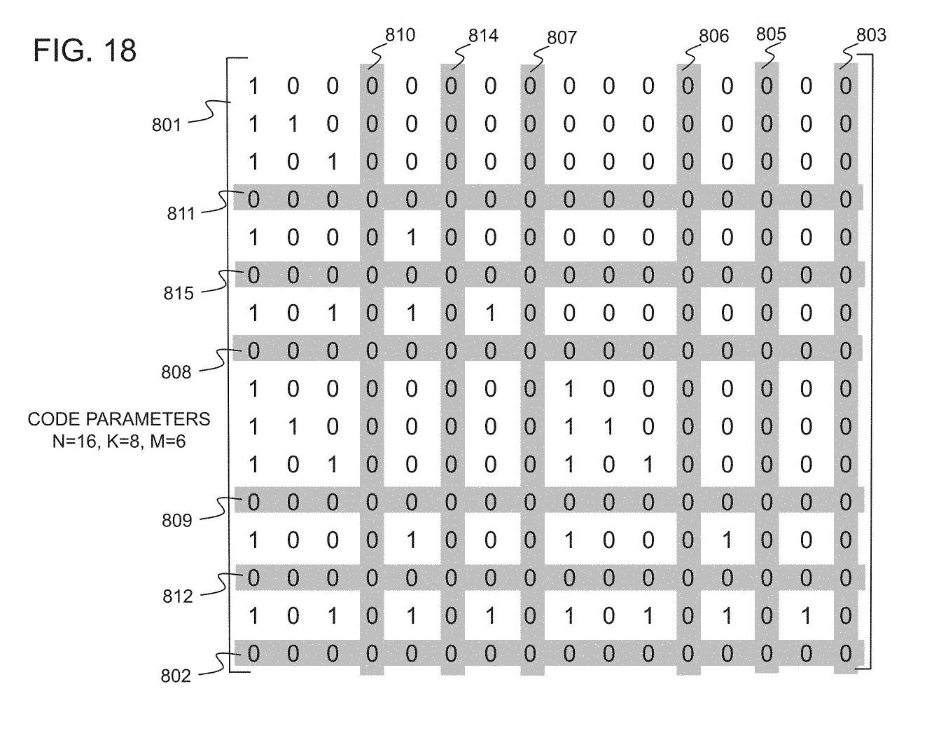

As illustrated in FIG. 18, after comparing the decoding error probabilities (or equivalently, Z parameter) of the indices of the columns 804, 813 and 814, the index of the column 814 is assumed to be selected as it has the maximum Z parameter among them. Thus the column 814 is filled with all zero. Since the row index corresponding to a position of value 1 in the column 814 is the row 815, the row 815 is also filled with all zero. The index of the column 814 is included in the puncturing array. The index of the row 815 is included in the frozen set.

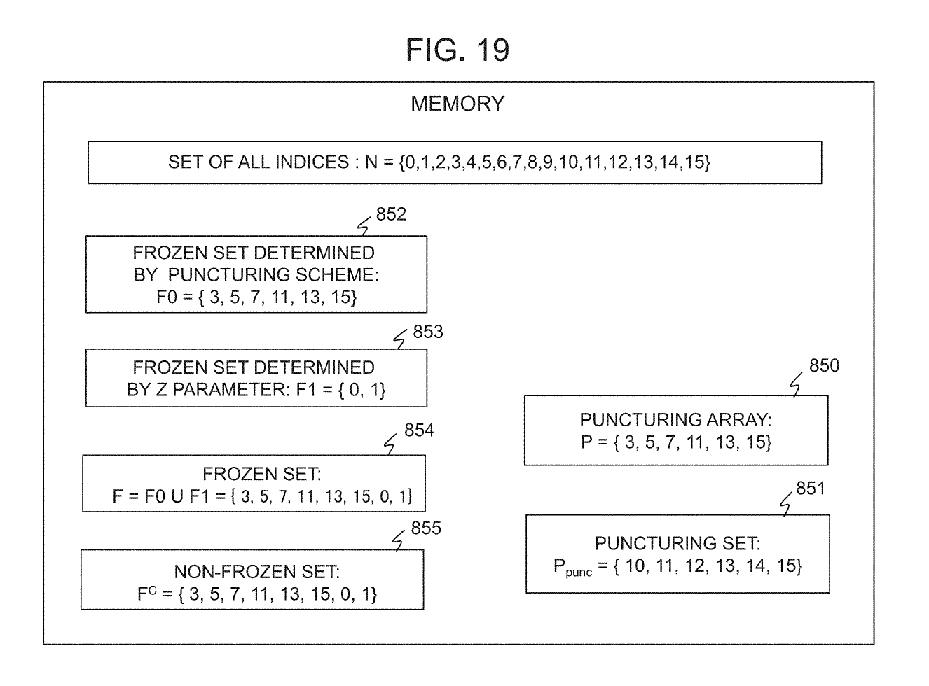

FIG. 19 shows the resulting puncturing array, puncturing set, frozen set and non-frozen set obtained according to the above-described example as shown in FIGS. 8-18. Considering a code length N=16, the set of all bit-channels or indices can be written from 0 to 15. Using the puncturing method in the case of M=6, a puncturing array P may be obtained as shown by reference numeral 850. A puncturing set P_{punc} may be obtained as shown by reference numeral 851 by performing bit-reversal operation on the puncturing array P. Based on the puncturing scheme, part of the frozen set F0 may be obtained as shown by reference numeral 852. The remaining N−K−M=2 indices of the frozen set F1 may be obtained according to the highest values of Z parameter as shown by reference numeral 853. The total frozen set F may be obtained as a union of the sets F0 and F1 as shown by reference numeral 854. The non-frozen set is a complementary set of the set of all bit-channels or indices and may be obtained as shown by reference numeral 855.

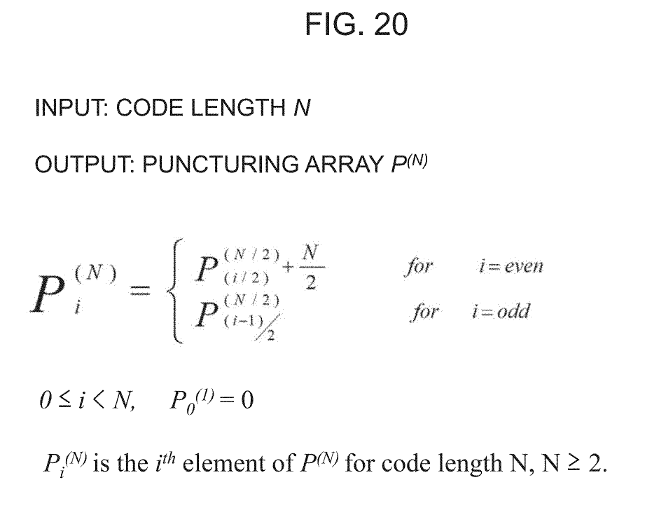

FIG. 20 shows a simple alternative algorithm to generate the same puncturing array as described above. The algorithm may require the code length N as input and may output the corresponding puncturing array P^{(N)}. As shown in FIG. 20, Pᵢ^{(N)} which is the i^{th} element of P^{(N)}, may be computed by the following equation:

$${P}_{i}^{( N )} = \{ \begin{matrix}{P}_{( i / 2 )}^{( N / 2 )} + \frac{N}{2} & for i = even \\ {P}_{( i - 1 ) / 2}^{( N / 2 )} & for i = odd\end{matrix} \qquad [ Math . 1 ]$$

where i is an integer not smaller than 0 but smaller than N, Pᵢ^{(N)} is the i^{th} element of P^{(N)} for code length N (N>=2), and P₀⁽¹⁾=0.
A bit-reversal permutation operation may be performed on P^{(N)} to generate a puncturing set P_{punc}.

### 3.3) Systematic Encoding and Decoding

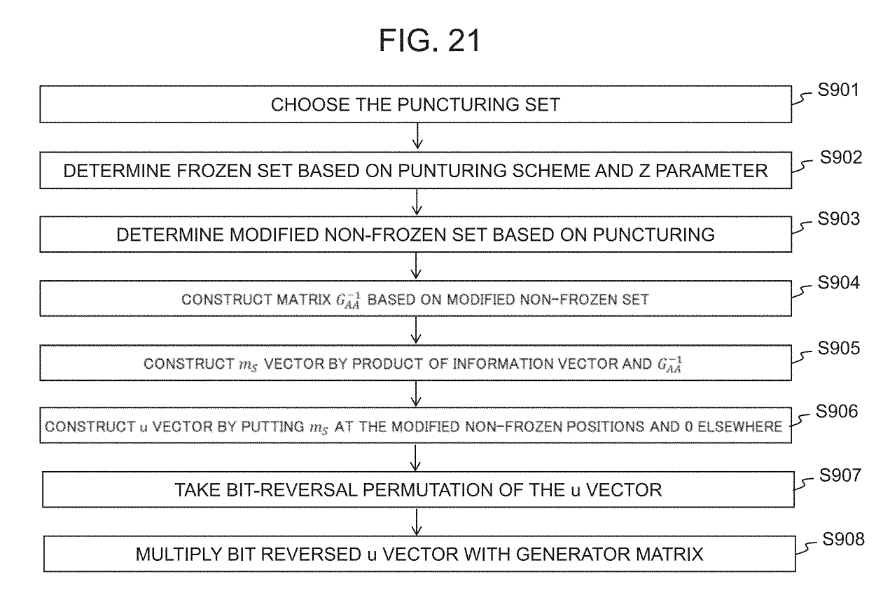

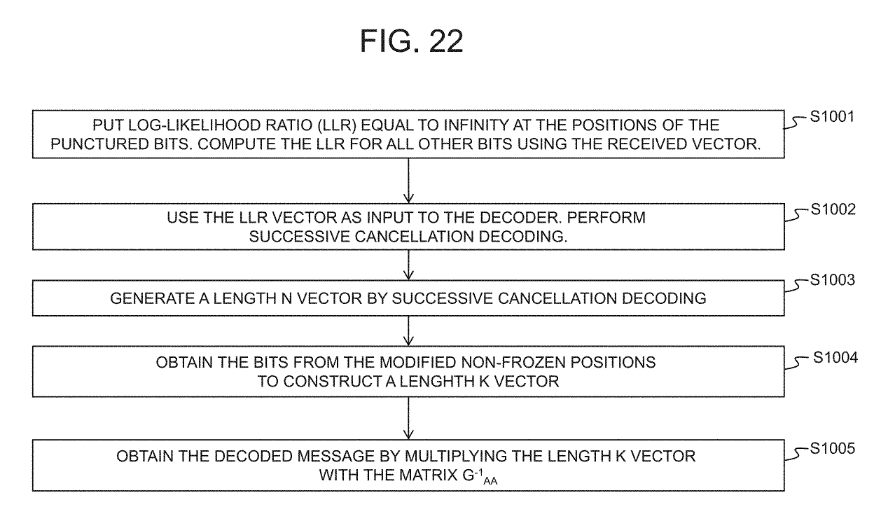

The encoding and decoding as described above are based on non-systematic encoding/decoding. Here, by referring to FIGS. 21 and 22, systematic encoding/decoding will be described.

FIG. 21 is a flowchart illustrating systematic encoding of Polar Codes according to an exemplary embodiment of the present invention. At first, the puncturing set can be constructed using the method discussed before in FIG. 3 (Operation S901). Then the frozen set is determined according to the method discussed before in FIG. 4 (Operation S902). The modified non-frozen set is then determined by taking a difference between the set of all indices and the frozen set (Operation S903). A K×K matrix G⁻¹_{AA} is constructed using the row and column elements corresponding to the non-frozen set, where K is the size of the non-frozen set (Operation S904). A vector mₛ of length K is then constructed by multiplying an information vector of length K with the matrix G⁻¹_{AA} (Operation S905). Next, an input vector u of length N is constructed by putting the elements of vector mₛ at the non-frozen positions and 0 elsewhere (Operation S906). Then a bit-reversal permutation is performed on the u vector (Operation S907). Finally, the bit-reversal permuted u vector is multiplied with the generator matrix to produce the codeword (Operation S908).

FIG. 22 is a flowchart illustrating systematic decoding of Polar Codes according to an exemplary embodiment of the present invention. This may be done by putting the log-likelihood ratio (LLR) values of the punctured bits to positive or negative infinity (Operation S1001). For instance, if the frozen index positions in the un-encoded vector at the encoder side was filled in with 0 bit, then positive infinity may be used as the LLR of the punctured positions by the decoder before decoding starts.

The decoder then uses the LLR vector of length N as the input and runs a decoding algorithm (Operation S1002). For example, the decoder may use a Successive Cancellation (SC) decoding or Successive Cancellation List (SCL) decoding algorithm. The decoder outputs a vector of length N after running the decoding algorithm (Operation S1003). The bits at the non-frozen positions of the decoder output are used to construct a vector of length K (Operation S1004). The vector constructed in the operation S1004 is then multiplied with the matrix G⁻¹_{AA} to obtain the decoded message (Operation S1005).

### 4. SECOND EXAMPLE

A second example for generating puncturing patterns in Polar Codes is introduced as follows. According to this example, it is possible to generate puncturing patterns that will achieve constant-valued punctured bits without any operation like row deletion or column deletion on the generator matrix. Instead, this method simply uses the binary expansion of the indices.

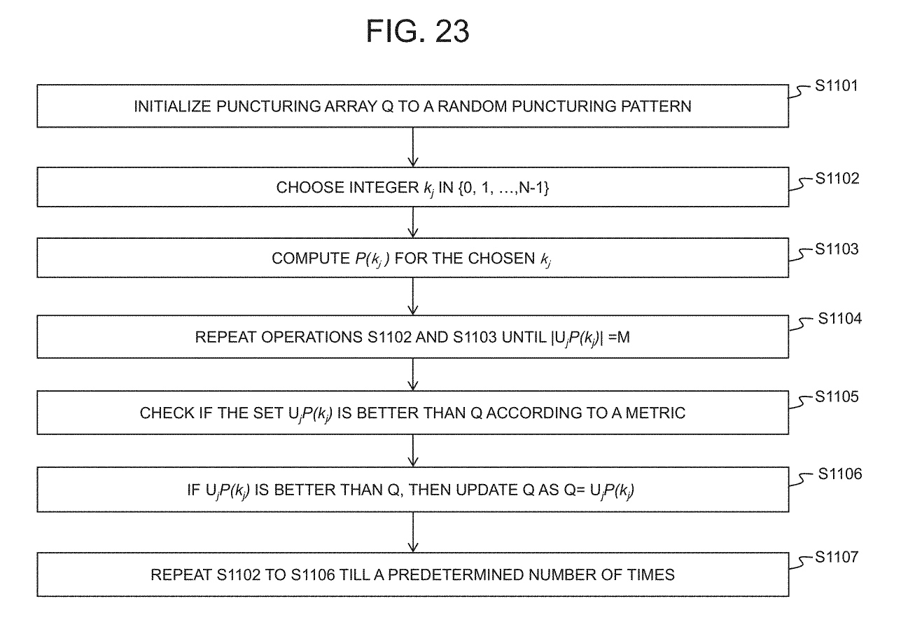

As illustrated in FIG. 23, at first, a puncturing array Q may be initialized to a randomly chosen puncturing array (Operation S1101). Alternatively, instead of a randomly chosen puncturing array, a good puncturing array (for example, a puncturing array as obtained by the method discussed before) may also be used as initial value in Q. Then an integer kⱼ may be chosen from {0, 1, . . . , N−1} (Operation S1102).

Here, the following expressions are employed. For an integer a (0=<a<N), let (a₀, a₁, . . . , aₙ₋₁) denote the binary expansion of a as follows:

a=Σᵣ₌₀ⁿ⁻¹aᵣ2^{r} [Math. 2]

where aᵣ∈{0, 1} for all r=0, 1, . . . , n−1 and n=log₂N. For two integers a and b (0=<a, b<N), let us denote

a [symbol] b [Math. 3]

if aᵣ>=bᵣ for all r=0, 1, . . . , n−1.

Then a set P(k) may be computed by the following formula (Operation S1103):

P(k)={u|u [symbol] k}, [Math. 4]

where u is an integer in {0,1, . . . , N−1} and

u [symbol] k [Math. 5]

represents uᵣ>=kᵣ for all r=0, 1, . . . , n−1.

The operations S1102 and S1103 may be repeated until the size of the union set UⱼP(kⱼ) is equal to M, where UⱼP(kⱼ) represents the union of sets P(kⱼ) corresponding to some chosen values of kⱼ in {0, 1, . . . , N−1} (Operation S1104). The symbol “U” here is a mathematical symbol to represent “union” of sets. |UⱼP(kⱼ)| in Operation S1104 represents the size or cardinality of the set UⱼP(kⱼ). Subsequently, the union set UⱼP(kⱼ) may be compared with the set Q with respect to a metric to find the better set between the two sets (Operation S1105). The metric used for comparison can be Bhattacharyya parameter of the indices contained in the union set UⱼP(kⱼ) and the set Q, without loss of generality. As an example, the sum of the Bhattacharyya parameters of the indices in the union set UⱼP(kⱼ) may be compared with the sum of the Bhattacharyya parameters of the indices in the set Q. Depending on which is found to be higher in value, the corresponding set may be adjudged to be a better set. Any other metric can also be used to find a better set between the two and any such metric should be construed to be in the scope of the present invention. For instance, such metric may be at least one of the sums of decoding error probabilities of the indices contained in the set and puncturing array, respectively; exponent of the punctured polarizing matrix; and the minimum distance of the punctured code.

If UⱼP(kⱼ) is found to be a better set with respect to the chosen metric, then UⱼP(kⱼ) is saved in Q (Operation S1106). The operations S1102 to S1106 may be repeated for a predetermined number of times to find the optimal set Q (Operation S1107). Alternatively, instead of repeating for a predetermined number of times, the operations S1102 to S1106 may be repeated so as to perform an exhaustive search for the optimal set Q with respect to the chosen metric. The set Q obtained at the end of the final iteration may be used as a puncturing array. Bit-reversal permutation of the obtained puncturing array may be used as a puncturing set.

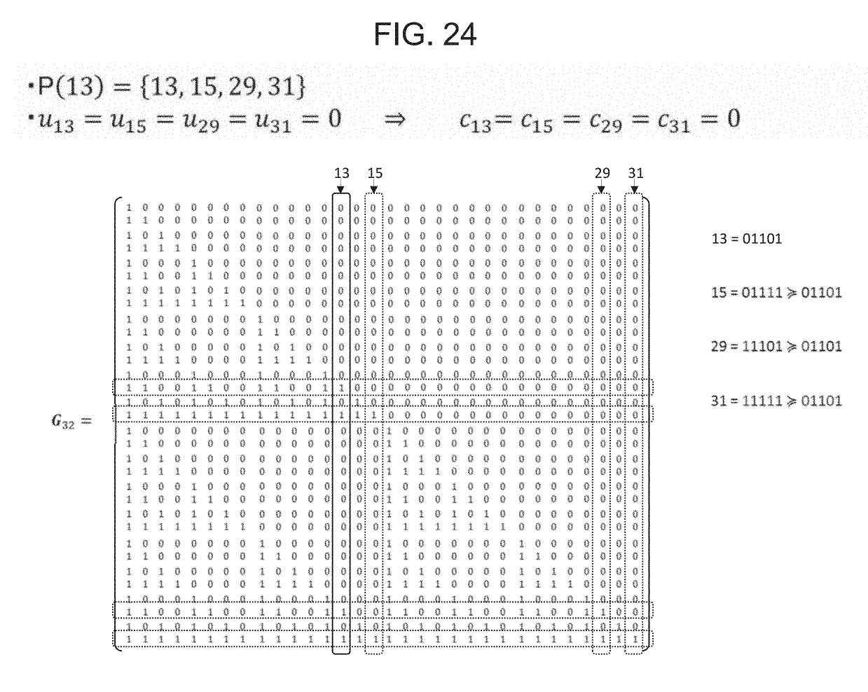

FIG. 24 illustrates an example of computing a set P(k) according to the method described above for a case of N=32. In this example, the set P(13) has been shown as follows: P(13)={13, 15, 29, 31}. This is because, each bit in the binary expansion of integer 13 is less or equal to the corresponding bit in the binary expansion of integers 15, 29, 31 and 13 itself. For all other integers in the range 0 to 31, at least one bit in their binary expansion is smaller than the corresponding bit in the binary expansion of integer 13. If the indices 13, 15, 29 and 31 are set to be frozen, it is possible to obtain a code bit of value 0 at the positions corresponding to the bit-reversal permuted values of {13, 15, 29, 31} in the output codeword. Thus, if the positions corresponding to the bit-reversal permuted values of {13, 15, 29, 31} are punctured in the output codeword, the decoder can still know that those positions had a value of 0 bit. The decoder may then set the initial LLR of the codebits at the positions corresponding to the bit-reversal permuted values of {13, 15, 29, 31} to infinity and start decoding.

Where applicable, various embodiments provided by the present disclosure may be implemented using hardware, software, or combinations of hardware and software. Also where applicable, the various hardware components and/or software components set forth herein may be combined into composite components comprising software, hardware, and/or both without departing from the spirit of the present disclosure. Where applicable, the various hardware components and/or software components set forth herein may be separated into sub-components comprising software, hardware, or both without departing from the spirit of the present invention. In addition, where applicable, it is contemplated that software components may be implemented as hardware components, and vice-versa.

Application software in accordance with the present disclosure, such as computer programs executed by the device and may be stored on one or more computer readable mediums. It is also contemplated that the steps identified herein may be implemented using one or more general purpose or specific purpose computers and/or computer systems, networked and/or otherwise. Where applicable, the ordering of various steps described herein may be changed, combined into composite steps, and/or separated into sub-steps to provide features described herein.

Although embodiments of the present disclosure have been described, these embodiments illustrate but do not limit the present invention.

It should also be understood that embodiments of the present disclosure should not be limited to these embodiments but that numerous modifications and variations may be made by one of ordinary skill in the art in accordance with the principles of the present disclosure and be included within the spirit and scope of the present disclosure as hereinafter claimed.

The above exemplary embodiments can be applied to wireless peer-to-peer (P2P) networks.

### 5. SUPPLEMENTARY NOTES

The whole or part of the exemplary embodiments disclosed above can be described as, but not limited to, the following supplementary notes.

### (Supplementary Note 1)

A communication device comprising:

an encoder that encodes an input vector to output a codeword of Polar Code;

a memory that is configured to store a frozen set of positions of frozen bits and a puncturing set of positions of punctured bits; and

at least one processor that is configured to execute a set of instructions to:

a) select at least one frozen index to make the punctured bit become constant-valued in the output codeword;

b) select the position of a punctured bit such that a minimum number of indices get frozen according to the step a);

c) freeze an index that has a highest decoding error probability among a plurality of indices according to the steps a) and b);

d) repeat the steps a) to c) a predetermined number of times to obtain an array of indices; and

e) perform a bit-reversal permutation of the array obtained in the step d) to generate the positions of the punctured bits in the puncturing set.

### (Supplementary Note 2)

The communication device according to Supplementary note 1, wherein in the step b), a single index gets frozen according to the step a).

### (Supplementary Note 3)

The communication device according to Supplementary note 1 or 2, wherein in the step b), at least one column having weight 1 is selected from a generator matrix for Polar Code.

### (Supplementary Note 4)

The communication device according to Supplementary note 3, wherein the step c) comprises:

comparing decoding error probabilities of a plurality of columns that have weight 1; and

selecting one column having the highest decoding error probability.

### (Supplementary Note 5)

The communication device according to Supplementary note 3 or 4, wherein the step c) further comprises:

including an index of a row corresponding to a position of value 1 in the one column into the frozen set.

### (Supplementary Note 6)

The communication device according to any one of Supplementary notes 1-4, wherein the step d) further comprises:

including the array of indices as positions of frozen bits into the frozen set.

### (Supplementary Note 7)

The communication device according to any one of Supplementary notes 1-6, wherein in the step d), the steps a) to c) are repeated for as many times as the number of bits needed to be punctured.

### (Supplementary Note 8)

The communication device according to any one of Supplementary notes 1-6, wherein the step d) further comprises:

replacing a row and a column of a generator matrix for Polar Code corresponding to the index obtained by the step c) with an all-zero row and all-zero column, respectively.

### (Supplementary Note 8_1)

The communication device according to any one of Supplementary notes 1-6, wherein the step d) further comprises:

deleting a row and a column of a generator matrix for Polar Code corresponding to the index obtained by the step c).

### (Supplementary Note 9)

The communication device according to Supplementary note 5 or 6, wherein the step d) further comprises:

selecting at least one index with a highest value of decoding error probability which is not in the frozen set to further include it into the frozen set so as to fill the remaining number of elements of the frozen set.

### (Supplementary Note 10)

The communication device according to any one of Supplementary notes 1-9, wherein the codeword encoded by the encoder is punctured at positions specified by the puncturing set before transmission.

### (Supplementary Note 11)

The communication device according to any one of Supplementary notes 1-10, wherein Bhattacharyya parameter is used as a metric for decoding error probability.

### (Supplementary Note 12)

The communication device according to any one of Supplementary notes 1-11, wherein the processor executes the set of instructions to compute the following equation:

$${P}_{i}^{( N )} = \{ \begin{matrix}{P}_{( i / 2 )}^{( N / 2 )} + \frac{N}{2} & for i = even \\ {P}_{( i - 1 ) / 2}^{( N / 2 )} & for i = odd\end{matrix} \qquad [ Math . 6 ]$$

where N is the code length of a Polar Code, i is an integer not smaller than 0 but smaller than N, Pᵢ^{(N)} is the i^{th} element of P^{(N)} for code length N (N>=2), P^{(N)} is a puncturing array for the Polar Code of N, and P₀⁽¹⁾=0.

### (Supplementary Note 13)

A communication system comprising:

a sender apparatus comprising the communication device according to any one of Supplementary notes 1-12; and

a receiver apparatus comprising a decoder that decodes encoded codeword received from the sender apparatus,

wherein a punctured bit has a constant value that is known to the decoder.

### (Supplementary Note 14)

The communication system according to Supplementary note 13, wherein the decoder sets an initial log-likelihood ratio value of the punctured bit to at least one of positive or negative infinity.

### (Supplementary Note 15)

The communication system according to Supplementary note 13 or 14, wherein at least one of a Successive Cancellation decoding algorithm, Successive Cancellation List decoding algorithm and Cyclic Redundancy Check (CRC)-aided Successive Cancellation List Decoding Algorithm is used by the decoder for decoding.

### (Supplementary Note 16)

A puncturing method for Polar Codes, comprising:

a) selecting at least one frozen index to make the punctured bit become constant-valued in the output codeword;

b) selecting the position of a punctured bit such that a minimum number of indices get frozen according to the step a);

c) freezing an index that has a highest decoding error probability among a plurality of indices according to the steps a) and b);

d) repeating the steps a) to c) a predetermined number of times to obtain an array of indices; and

e) performing a bit-reversal permutation of the array obtained in the step d) to generate the positions of the punctured bits in the puncturing set.

### (Supplementary Note 17)

The puncturing method according to Supplementary note 16, wherein the step c) comprises:

comparing decoding error probabilities of a plurality of columns that have weight 1; and

selecting one column having the highest decoding error probability.

### (Supplementary Note 18)

The puncturing method according to Supplementary note 16, wherein the step d) further comprises:

including the array of indices as positions of frozen bits into the frozen set.

### (Supplementary Note 19)

The puncturing method according to Supplementary note 17, wherein the step c) further comprises:

including an index of a row corresponding to a position of value 1 in the one column into the frozen set.

### (Supplementary Note 20)

The puncturing method according to Supplementary note 18 or 19, wherein the step d) further comprises:

selecting at least one index with a highest value of decoding error probability which is not in the frozen set to further include it into the frozen set so as to fill the remaining number of elements of the frozen set.

### (Supplementary Note 21)

The puncturing method according to any one of Supplementary notes 16-20, wherein Bhattacharyya parameter is used as a metric for decoding error probability.

### (Supplementary Note 22)

The puncturing method according to any one of Supplementary notes 16-21, wherein the steps a)-d) are executed by computing the following equation:

$${P}_{i}^{( N )} = \{ \begin{matrix}{P}_{( i / 2 )}^{( N / 2 )} + \frac{N}{2} & for i = even \\ {P}_{( i - 1 ) / 2}^{( N / 2 )} & for i = odd\end{matrix} \qquad [ Math . 7 ]$$

where N is the code length of a Polar Code, i is an integer not smaller than 0 but smaller than N, Pᵢ^{(N)} is the i^{th} element of P^{(N)} for code length N (N>=2), P^{(N)} is a puncturing array for the Polar Code of N, and P₀⁽¹⁾=0.

### (Supplementary Note 23)

A program to function a computer as a sender device including an encoder for Polar Codes, the program comprising a set of instructions to:

a) select at least one frozen index to make the punctured bit become constant-valued in the output codeword;

b) select the position of a punctured bit such that a minimum number of indices get frozen according to the step a);

c) freeze an index that has a highest decoding error probability among a plurality of indices according to the steps a) and b);

d) repeat the steps a) to c) a predetermined number of times to obtain an array of indices; and

e) perform a bit-reversal permutation of the array obtained in the step d) to generate the positions of the punctured bits in the puncturing set.

### (Supplementary Note 24)

A method of designing a puncturing pattern for a codeword of Polar Code such that the punctured bits have constant value, the method comprising:

selecting a part of the frozen indices set such that punctured bits have a constant value; and

selecting a puncturing set such that a least number of bit indices get frozen and bit indices with relatively higher value of decoding error probability gets frozen.

### (Supplementary Note 25)

The method according to Supplementary note 24, wherein a puncturing position is determined by selecting a column of a generator matrix of Polar Code that has column weight unity.

### (Supplementary Note 26)

The method according to Supplementary note 24 and 25, wherein in response to multiple columns with column weight unity, an index among them that has highest value of decoding error probability is selected for puncturing.

### (Supplementary Note 27)

The method according to any one of Supplementary notes 24-26, wherein rows of the generator matrix that have value 1 in the column index selected for puncturing is included in a set of frozen indices.

### (Supplementary Note 28)

The method according to Supplementary note 25, wherein an index corresponding to the selected column is included in a frozen set of positions of frozen bits.

### (Supplementary Note 29)

The method according to any one of Supplementary notes 24-28, wherein the frozen set is determined by:

a first operation where part of the frozen indices set is determined such that the punctured bits have the constant value,

a second operation where the remaining part of the frozen indices set is determined by selecting the bit indices with highest decoding error probabilities from the remaining indices not included to frozen set by first operation.

### (Supplementary Note 30)

A communication device comprising:

an encoder that encodes an input vector to output a codeword of Polar Code;

a memory that is configured to store a frozen set of positions of frozen bits and a puncturing set of positions of punctured bits; and

at least one processor that is configured to execute a set of instructions to:

a) initialize a puncturing array Q;

b) choose an integer kⱼ in the range 0 to N−1 and compute a set P(kⱼ);

c) repeat the step (b) until the size of an union set UⱼP(kⱼ) becomes equal to M, where UⱼP(kⱼ) is computed as union of sets P(kⱼ) for kⱼ in {0, 1, . . . , N−1} and M is the length of puncturing set;

d) responsive to determining that the set UⱼP(kⱼ) becomes better than the puncturing array Q with respect to a predetermined metric, update the puncturing array Q by the set UⱼP(kⱼ);

e) repeat the steps b), c) and d) until a best puncturing array Q with respect to the predetermined metric is obtained; and

f) calculate bit-reversal permutation of the best puncturing array Q to generate the positions of the punctured bits in the puncturing set.

### (Supplementary Note 31)

The communication device according to 30, wherein in the step a), the puncturing array is initialized to a randomly chosen array of length M with elements in the range 0 to N−1 in a non-repetitive manner.

### (Supplementary Note 32)

The communication device according to 30, wherein in the step a), the puncturing array is initialized to a good puncturing array generated by the method according to any one of Supplementary note 16-22.

### (Supplementary Note 33)

The communication device according to any one of Supplementary notes 30-32, wherein in the step b), the set P(kⱼ) is computed by

P(k)={u|u [symbol] k}, [Math. 8]

where u is an integer in {0, 1, . . . , N−1} and

u [symbol] k [Math. 9]

represents uᵣ>=kᵣ for all r=0, 1, . . . , n−1.

### (Supplementary Note 34)

The communication device according to any one of Supplementary notes 30-33, wherein in the step d), the predetermined metric is at least one of:

sums of decoding error probabilities of the indices contained in the union set UⱼP(kⱼ) and the puncturing array, respectively;

an exponent of the punctured polarizing matrix; and

the minimum distance of the punctured code.

### (Supplementary Note 35)

The communication device according to any one of Supplementary notes 30-34, wherein in the step e), the steps b), c) and d) are repeated for a predetermined number of times to obtain the best puncturing array or a number of times so as to perform an exhaustive search to obtain the best puncturing array with respect to the chosen metric.

### (Supplementary Note 36)

The communication device according to any one of Supplementary notes 30-35, wherein in the step e), the indices in the best puncturing array are set to be frozen.

### (Supplementary Note 37)

The communication device according to any one of Supplementary notes 30-36, wherein bits corresponding to the indices in the puncturing set obtained in the step f) are punctured in the encoded codeword before transmission.

### (Supplementary Note 38)

A communication system comprising:

a sender apparatus comprising the communication device according to any one of Supplementary notes 30-37; and

a receiver apparatus comprising a decoder that decodes encoded codeword received from the sender apparatus,

wherein a constant value of punctured bits is known to the decoder.

### (Supplementary Note 39)

The communication system according to Supplementary note 38, wherein the decoder initializes the log-likelihood values of the punctured bits corresponding to the positions obtained in the step f) to at least one of positive or negative infinity.

What is claimed is:

1. A communication device comprising:
an encoder that encodes an input vector to output a codeword of polar code;
a memory that is configured to store a frozen set of positions of frozen bits and a puncturing set of positions of punctured bits; and
at least one processor that is configured to execute a set of instructions to:
a) set the frozen set such that a punctured bit has a constant value;
b) select the position of a punctured bit such that a minimum number of indices get frozen according to the step a);
c) freeze an index that has a highest decoding error probability among a plurality of indices selected according to the step a) and b);
d) repeat the steps b) and c) a predetermined number of times to obtain an array of indices; and
e) perform a bit-reversal permutation of the array obtained in the step d) to generate the positions of the punctured bits in the puncturing set such that code bits of polar code at the indices of the puncturing set are not transmitted.

2. The communication device according to claim 1, wherein in the step b), a single index gets frozen according to the step a).

3. The communication device according to claim 1, wherein in the step b), at least one column having weight 1 is selected from a generator matrix for polar code, and
subject to the condition that a plurality of columns with weight 1 are available, the step c) comprises comparing decoding error probabilities of a plurality of columns that have weight 1; and selecting one column having the highest decoding error probability.

4. (canceled)

5. The communication device according to claim 1, wherein the at least one processor is further configured to execute instructions to perform at least one of:
a step of including an index of a row corresponding to a position of value 1 in the one column into the frozen set in the step c) and
a step of including the array of indices in the step d) as positions of frozen bits into the frozen set.

6-7. (canceled)

8. The communication device according to claim 1, wherein the step d) further comprises:
replacing a row and a column of a generator matrix for polar code corresponding to the index obtained by the step c) with an all-zero row and all-zero column, respectively.

9. (canceled)

10. The communication device according to claim 5, wherein the step d) further comprises:
subject to the condition that number of elements in frozen set after step d) is less than the desired number of elements in the frozen set, selecting at least one index with a highest value of decoding error probability which is not in the frozen set to further include it into the frozen set so as to fill the remaining number of elements of the frozen set.

11-12. (canceled)

13. The communication device according to claim 1, wherein the processor executes the set of instructions to compute the following equation:
$${P}_{i}^{( N )} = \{ \begin{matrix}{P}_{( i / 2 )}^{( N / 2 )} + \frac{N}{2} & for i = even \\ {P}_{( i - 1 ) / 2}^{( N / 2 )} & for i = odd\end{matrix} \qquad [ Math . 10 ]$$
where N is the code length of a polar code, i is an integer not smaller than 0 but smaller than N, Pᵢ^{(N)} is the i^{th} element of P^{(N)} for code length N (N>=2), P^{(N)} is an array of indices of d), and P₀⁽¹⁾=0.

14. A communication system comprising:
a sender apparatus comprising the communication device according to claim 1; and
a receiver apparatus comprising a decoder that decodes encoded codeword received from the sender apparatus,
wherein a punctured bit has a constant value that is known to the decoder.

15-23. (canceled)

24. A program to function a computer as a sender device including an encoder for polar codes, the program comprising a set of instructions to:
a) set the frozen set such that a punctured bit has a constant value;
b) select the position of a punctured bit such that a minimum number of indices get frozen according to the step a);
c) freeze an index that has a highest decoding error probability among a plurality of indices according to the steps a) and b);
d) repeat the steps b) and c) a predetermined number of times to obtain an array of indices; and
e) perform a bit-reversal permutation of the array obtained in the step d) to generate the positions of the punctured bits in the puncturing set such that code bits of polar code at the indices of the puncturing set are not transmitted.

25. A method of designing a puncturing pattern for a codeword of polar code such that the punctured bits have constant value, the method comprising:
selecting a part of the frozen indices set such that punctured bits have a constant value; and
selecting a puncturing set such that a least number of bit indices get frozen.

26-29. (canceled)

30. The method according to claim 25, wherein the frozen set is determined by:
a first operation where part of the frozen indices set is determined such that the punctured bits have the constant value,
a second operation where the remaining part of the frozen indices set is determined by selecting the bit indices with highest decoding error probabilities from the remaining indices not included to frozen set by first operation.

31. A communication device comprising:
an encoder that encodes an input vector to output a codeword of polar code;
a memory that is configured to store a frozen set of positions of frozen bits and a puncturing set of positions of punctured bits; and
at least one processor that is configured to execute a set of instructions to:
a) initialize a puncturing array Q;
b) choose an integer kⱼ in the range 0 to N−1 and compute a set P(kⱼ) where N is the length of polar code before puncturing;
c) repeat the step (b) until the size of an union set UⱼP(kⱼ) becomes equal to M, where UⱼP(kⱼ) is computed as union of sets P(kⱼ) for kⱼ in {0, 1, . . . , N−1} and M is the length of puncturing set;
d) responsive to determining that the set UⱼP(kⱼ) becomes better than the puncturing array Q with respect to a predetermined metric, update the puncturing array Q by the set UⱼP(kⱼ);
e) repeat the steps b), c) and d) until a best puncturing array Q with respect to the predetermined metric is obtained; and
f) calculate bit-reversal permutation of the best puncturing array Q to generate the positions of the punctured bits in the puncturing set.

32. The communication device according to claim 31, wherein in the step a), the puncturing array is initialized to at least one of
a randomly chosen array of length M with elements in the range 0 to N−1 in a non-repetitive manner and
a good puncturing array generated by at least one of
a method according to a puncturing method comprising:
i) setting the frozen set such that a punctured bit has a constant value:
ii) selecting the position of a punctured bit such that a minimum number of indices get frozen according to the step i);
iii) freezing an index that has a highest decoding error probability among a plurality of indices according to the steps i) and ii), and also including the index in the good puncturing array;
iv) repeating the steps -ii) and iii) for M number of times to obtain the good puncturing array.
and a method wherein steps i)-iv) are executed by computing the following equation:
$${P}_{i}^{( N )} = \{ \begin{matrix}{P}_{( i / 2 )}^{( N / 2 )} + \frac{N}{2} & for i = even \\ {P}_{( i - 1 ) / 2}^{( N / 2 )} & for i = odd\end{matrix}$$
where N is the code length of a polar code, i is an integer not smaller than 0 but smaller than N, Pⱼ^{(N)} is the i^{th} element of P^{(N)} for code length N (N>=2), P^{(N)} is a puncturing array for the polar code of N, and P₀⁽¹⁾=0.

33. (canceled)

34. The communication device according to claim 31, wherein in the step b), the set P(kⱼ) is computed by
P(k)={u|u [symbol] k}, [Math. 12]
where u is an integer in {0, 1, . . . , N−1} and
u [symbol] k [Math. 13]
represents uᵣ>=kᵣ for all r=0, 1, . . . , n−1, where uᵣ and kᵣ represent the r^{th} bit in the binary expansion of u and k respectively, n is logarithm with base 2 of N.

35. The communication device according to claim 31, wherein in the step d), the predetermined metric is at least one of:
sums of decoding error probabilities of the indices contained in the union set UⱼP(kⱼ) and the puncturing array Q, respectively;
an exponent of the punctured polarizing matrix; and
the minimum distance of the punctured code.

36. (canceled)

37. The communication device according to claim 31, wherein the indices in the best puncturing array obtained in the step e) are set to be frozen, and the indices in the puncturing set obtained in step f) are punctured in the codeword before transmission.

38-40. (canceled)

41. The communication device according to claim 13, wherein at least one index contained in P^{(N)} is included in frozen set, and the bit-reversed permuted index of the at least one index is included in puncturing set such that the codebit at the index contained in puncturing set is not transmitted.

42. The method according to claim 25, wherein
a puncturing position is obtained by bit-reversal permutation of at least one index Pᵢ^{(N)} computed by the equation
$${P}_{i}^{( N )} = \{ \begin{matrix}{P}_{( i / 2 )}^{( N / 2 )} + \frac{N}{2} & for i = even \\ {P}_{( i - 1 ) / 2}^{( N / 2 )} & for i = odd\end{matrix}$$
and included in a puncturing set;
a frozen index is obtained from at least one index Pᵢ^{(N)} computed by the equation and included in a frozen set;
subject to the condition that number of frozen indices is less than the desired number of frozen indices in the frozen set, a remaining number of frozen indices is obtained by selecting at least one index with a highest value of decoding error probability which is not in the frozen set to further include it into the frozen set,
where N is the code length of a polar code, i is an integer not smaller than 0 but smaller than N, Pᵢ^{(N)} is the i^{th} element of P^{(N)} for code length N (N>=2), P^{(N)} is an array of indices and P₀⁽¹⁾=0.

43. The method according to claim 42, further comprising:
storing, in a first memory, at least one puncturing position; and
storing, in a second memory, at least one frozen index,
wherein bit at the output of a polar encoder at the puncturing position is not transmitted, and
wherein bit at the input of a polar encoder at the frozen index is set to a constant value.

44. The method according to claim 30, wherein in the first operation:
a column index of generator matrix with column weight unity is selected;
at least one of a row of generator matrix that has value 1 in the selected column and the selected column index is included in a set of frozen indices;
an index obtained by bit-reversal permutation of the selected column index is included in a puncturing set such that bits of polar codeword at the indices contained in puncturing set are not transmitted.
